(19) United States
(12) Patent Application Publication
(10) Pub. No.: US 2005/0161778 A1
(43) Pub. Date: Jul. 28, 2005

(54) Power module and power module assembly

(75) Inventor: Jean-Michel Morelle, Beaugency (FR)

Correspondence Address: James R Williams;Jamison Seltzer Harper & Williams, 2625 Wilmington Road, New Castle, PA, 16105, US

(73) Assignee: Valeo Electronique et Systemes de Liaison, Montigny-le-Bretonneux (FR)

(21) Appl. No.: 10/498,855

(22) PCT Filed: Dec. 12, 2002
(86) PCT No.: PCT/FR02/04323

(30) Foreign Application Priority Data
Dec. 13, 2001 (FR) 01/16153

(51) Int. Cl. H01L 23/02

(52) U.S. Cl. 257/678

(57) ABSTRACT

The one-piece power module (12) comprises at least one cut-out metal trace (14), at least one electronic power component (16) electrically connected to the cut-out metal trace, and an electrically insulating material (30; 56) providing the power module with cohesion. The power module presents a cooling face (28) for putting directly into contact with cooling means external to the module. At least a portion of said cooling face (28) comprises the cut-out metal trace.

The present invention relates to a one-piece power module comprising at least one cut-out metal trace, at least one electronic power component electrically connected to the cut-out metal trace, and an electrically insulating material providing the power module with cohesion. The module presents a cooling face for putting into direct contact with cooling means external to the module.

The invention also relates to a power module assembly.

In general, a power module of the above-specified type comprises at least one electronic power component that is soldered or bonded onto a substrate.

By way of example, the substrate may be of the direct bounded copper (DBC) type comprising three layers. A first layer is constituted by an etched metal trace forming the connections of an electric circuit, an intermediate, second layer is a plate of electrically-insulating material such as a ceramic, e.g. alumina, and a third layer is a metal plate constituted by copper or by nickel-plated copper. The assembly constituted by the DBC type substrate and electronic power components soldered or bonded thereto is in turn soldered to a copper plate forming a mechanical support and a heat dissipator.

It is also possible for the substrate to be of the insulated metal substrate (IMS) type. In which case, the ceramic plate is replaced by a resin plate suitable for supporting a first layer constituted by a metal trace of very thin copper. In which case, the heat-dissipating third layer can be constituted by a metal plate made of aluminum.

When the substrate used is a substrate of the DBC type, the power module is robust and can accommodate high power, but at a cost price that is high. When the substrate is of the IMS type, the cut-out metal trace can be more complex and it is possible to place a larger number of electronic power components thereon, but the module is less good at withstanding high powers and severe environmental stresses.

In both cases, the path followed by heat between the electronic power components and cooling means external to the power module is long since the heat must pass through at least the various layers of the substrate.

The invention seeks to remedy the drawbacks of conventional power modules by providing a power module that is inexpensive to fabricate, and of a structure that enables effective cooling to be provided using external cooling means.

The invention thus provides a power module of the above-specified type, characterized in that at least a portion of said cooling face comprises the cut-out metal trace.

Thus, contact between the cut-out metal trace and the external cooling means is direct, thereby significantly shortening the path followed by heat. In addition, the absence of heat-dissipating insulating layers between the cut-out metal trace and the cooling means enables fabrication costs to be reduced.

A power module of the invention may also comprise one or more of the following characteristics:
the cut-out metal trace comprises tracks between which there remain gaps, and the cooling face comprises the tracks of the cut-out metal trace and electrically-insulating complementary portions which fill the gaps;
the complementary portions are overmolded around the tracks of the cut-out metal trace;
the electrically-insulating material forms a package whose bottom constitutes at least a portion of the cooling face;
the package includes an inside space defined by side walls and containing the electronic power component and its means for connection to the cut-out metal trace, and a filler material fills the empty space around the electronic power component and its connection means between the side walls;
the filler material is selected from a silicone gel and an epoxy or polyurethane type resin;
the electrically-insulating material forms an overmolded block around the cut-out metal trace and the electronic power component;
the module includes tabs for supporting and electrically connecting the cut-out metal trace to elements external to the module;
the elements external to the power module include means for controlling it;
the electronic power component is one of the elements selected from: a diode; a metal oxide on silicon (MOS) type transistor; an insulated gate bisolar type transistor (IGBT); and an application specific type integrated circuit (ASIC); and
the electrically-insulating material is a resin of epoxy or polyurethane type.

The invention also provides a power module assembly comprising at least one power module of the above-specified type, characterized in that it includes a face including the cooling face of each power module.

A power module assembly of the invention may also comprise the characteristic whereby it includes an assembly package whose bottom constitutes at least a portion of the face including the cooling face of each power module.

The invention will be better understood from the following description given purely by way of example and made with reference to the accompanying drawings, in which:

FIG. 1 is a diagrammatic section of a power module assembly in a first embodiment of the invention;

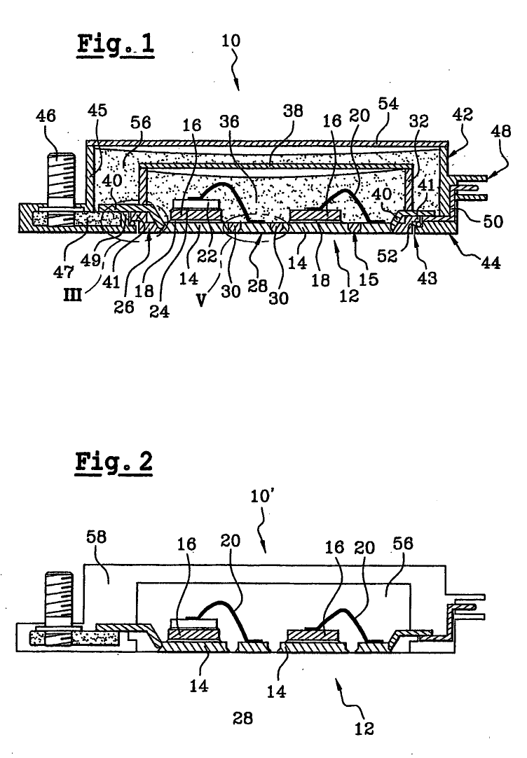

FIG. 2 is a diagrammatic section of a power module assembly in a second embodiment of the invention;

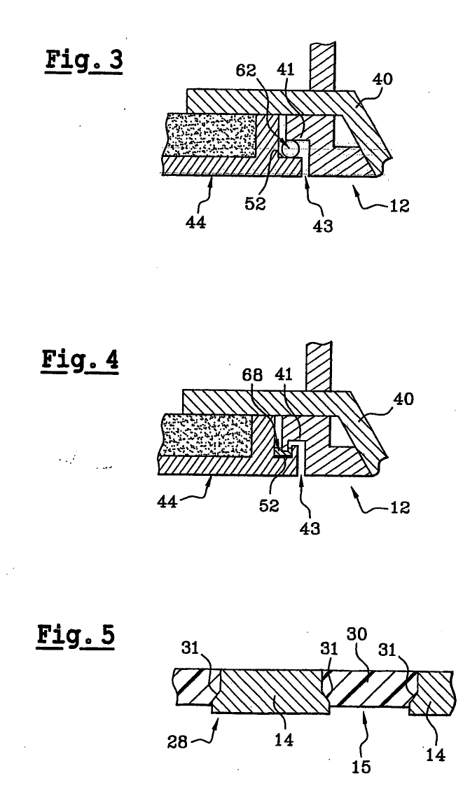

FIGS. 3 and 4 are enlargements of detail III in FIG. 1, showing two variants thereof; and

FIG. 5 is an enlargement of detail V in FIG. 1, showing one variant thereof.

The power module assembly 10 shown in FIG. 1 may comprise a plurality of power modules 12, only one of which is shown in the figure, united in a single assembly package 42.

The power module 12 comprises a cut-out metal trace 14 forming at least one set of electrical connections on which electronic power components 16 are disposed. The metal trace 14 is cut up into tracks between which there remain gaps 15 forming passages passing through the thickness of the metal trace 14. By way of example, an electronic power component 16 is a two-terminal component such as a diode, a three-terminal component such as a transistor of the MOS or IGBT type, or indeed a component that is more complex such as an integrated circuit of the ASIC type.

In the example shown in FIG. 1, each electronic power component 16 is fixed to the cut-out metal trace 14 by soldering 18 that also serves to provide an electrical contact between the component and the metal trace. The free face of each electrical power component 16 opposite from its face soldered to the metal trace 14 is itself electrically connected to another point of the metal trace 14.

This connection is provided by a metal strip 20 that is welded or soldered firstly to the cut-out metal trace 14 and secondly either directly to the free face of the electronic power component 16, or to a metal plate 22 secured to the free face of the electronic power component 16 by means of solder 24. The metal strip 20 is of a section that is a function of the current it is to carry. Nevertheless, it is dimensioned in thickness and in length so as to be capable of deforming, in particular due to thermal expansion, without exerting mechanical stress on the electronic power component 16.

The power module 12 comprises a resin package 26 containing the components 16. The bottom 28 of this package is composite: it is made up of the cut-out metal trace 14 supporting the components 16 and complementary resin portions 30 filling the gaps 15 in the metal trace.

Thus, seen in section, the bottom 28 appears as a one-piece plate that is the result of assembling together the disjoint metal tracks of the cut-out metal trace 14 and the resin portions 30 of the same thickness that unite them.

This bottom 28 constitutes a cooling face for the power module 12 that is for putting into contact with external cooling means (not shown).

One suitable method for obtaining the resin portions 30 is to mold them around the cracks of the cut-out metal trace 14. In which case, each gap 15 is filled with resin in the molten state during overmolding.

The mechanical retention of each resin portion 30 in the gap 15 containing it is provided by complementary shapes. In the example shown, these are cup-shapes, obtained by tapering the section of each gap in the form of two opposite sloping flats 31 as can be seen in FIG. 5.

It will be understood that this cup-shape prevents each resin portion 30 from escaping from the gap 15 to the outside of the package 26.

On the inside of the package 26, a filler material 36, such as a silicone gel, an epoxy resin, or a polyurethane resin, for example, fills the empty space around the electronic power components 16 and their means for connection to the cut-out metal trace 14, between side walls 32 defining the package 26.

This filler material 36 prevents the resin portions 30 from escaping from the bottom face 28 into the inside of the package 26.

Thus, by the combined action of the cup-shape and of the filler material 36, the resin portions 30 are secured to the tracks and provide mechanical strength or cohesion to the cut-out metal trace 14.

Cumulatively, the filler material 36 forms a rigid mass which provides cohesion to the power module 12 as a whole and causes it to act as a one-piece block.

A rigid cover 38 closes the package 26. Such a cover is justified only when the filler material 36 is not sufficiently rigid to provide satisfactory protection for the electronic power components 16, as is the case for a silicone gel.

Passing through each side wall 32 of the package 26, the power module 12 has tabs 40 for supporting and electrically connecting the metal trace to the outside of the module.

Finally, a peripheral collar 41 extends around the package 26, immediately beneath the tabs 40. This collar performs a sealing function which is described below with reference to FIGS. 3 and 4.

The assembly package 42 for containing a plurality of modules 12 comprises a bottom 44 pierced by openings 43 each of which is slightly larger than the bottom 28 of the corresponding power module.

The assembly package 42 also has side walls 45 that are taller than the package 26 of a power module 12 so that said side walls co-operate with one another to define a volume suitable for containing said power module in full.

Electrical connectors 46, 48 are provided on the assembly package 42 for connecting each power module 12 both to a power source (not shown) and also to external devices (not shown).

The electrical connection to the power source takes place via a conductive stud 46 supported by a lateral projection from the assembly package 42, this projection containing a metal strip 47 which extends from the base of the stud 46 to the inside of the assembly package, where a terminal portion of said metal strip 47 penetrates into the inside of the package that is to be found in a receptacle constituted by the bottom 44 of the assembly package 42 and by an inside edge 49 projecting from said bottom. This receptacle is upwardly open (as shown in FIG. 1), i.e. open away from the bottom 44. The terminal portion of the metal strip 47 is thus uncovered and can provide electrical connection with the power module 12, as described below.

Connection means are also provided for each input/output with the external devices. In the example shown, an external connector 48 contains a metal strip 50 which extends to the inside of the assembly package 42, bearing against its bottom and presenting, like the above-described metal strip 47, a terminal portion that is uncovered enabling an electrical connection to be made with the power module 12.

The outline of each opening 43 formed in the bottom 44 of the assembly package 42 is shaped to form a shoulder 52 whose bearing surface is directed towards the inside of said assembly package 42.

This shoulder is of dimensions suitable for co-operating with the peripheral collar 41 of the package 26 of the power module 12 so that the outside face of the bottom 28 of said package 26 is flush with the outside face of the bottom 44 of the assembly package 42.

Thus, each package 26 of the power module 12 closes the corresponding opening 43 of the assembly package 42 by extending the bottom 44 thereof.

A filler material 56 fills the empty volume in the assembly package 42 around the power module 12, and an optional cover 54 covers the entire inside volume of the assembly package, being secured to the top ends of the side walls 42.

The manner in which one or more power modules 12 are put into place in the assembly package 42 is described below.

The assembly package 42, without a cover, is presented in the position shown in FIG. 1, and each power module 12 is engaged from above into the inside of the assembly package 42 in register with a corresponding opening 43.

The bottom 28 of each power module 12 penetrates into the corresponding opening 43 and comes to occupy the same plane as the bottom of the assembly package 42, while the peripheral collar 41 thereof comes to rest against the shoulder 52 formed in the outline of the opening 43.

Simultaneously, the support and electrical connection tabs 40 take up their places on the metal strips 47 and 50 of the connectors 46 and 48 of the assembly package 42.

The power module 12 then rests via its support and connection tabs 40 inside the assembly package 42. The support and connection tabs 40 are then soldered or welded to the metal strips 47 and 50 in order to provide a high quality connection with the outside.

After this operation, the filler material 56 is introduced into the assembly package 42 in order to occupy the available volume around the power module 12, and then the assembly package is closed by putting the cover 54 into place.

The power module assembly 10′ shown in FIG. 2 constitutes a second embodiment of the invention.

In this embodiment, the package 26 is replaced by a block of resin 56 having the same volume, that is overmolded around the cut-out metal trace 14, the electronic power component 16, and the metal strips 20. As before, the metal trace 14 constitutes a portion of the bottom 28 of the power module 12 that is to be put into contact with external cooling means.

In this embodiment, the assembly package 42 is replaced by another block of resin 58 overmolded around the block of resin 56 which presents a volume identical to that of the assembly package 42.

The electrical contacts between the support and connections tabs 40 and the connectors 46 and 48 of the assembly 10′ are identical to those of the assembly 10.

FIG. 3 shows a detail of a support and connection tab 40 of the power module 12 resting on the bottom 44 of the power module assembly 10 shown in FIG. 1.

It can also be seen that by resting on the shoulder 52, the collar 41 provides sealed closure of the opening 43 of the assembly package 42, thus making it possible to pour the filler material 56 into the assembly package 42 prior to closing the cover 54.

In the present description, “sealed closure” is used to mean closing sufficiently to ensure that the filler material 56 does not escape through the bottom of the assembly package 42.

A first solution for providing such sealing is shown in FIG. 3, and consists in placing an adhesive tape 62 between the collar 41 and the shoulder 52.

Another solution, shown in FIG. 4, consists in providing a projection on each of the two facing faces constituted by the collar 41 and the shoulder 52, this projection being located on the free edge of said face, so that it co-operates with said face to define a groove suitable for receiving the projection from the other face.

The bottom of the groove formed on the shoulder 52 is lined with adhesive 68 against which the projection from the collar 41 comes to bear.

FIG. 5 shows a detail of the bottom 28 of the power module 12 in a variant embodiment. In this figure, it can be seen that in this variant the cut-out metal trace 14 projects from the overmolded resin 30. Thus, when the bottom 28 is put into contact with the external cooling means, it is the cut-out metal trace 14 that comes directly into contact therewith.

This configuration is obtained by having a cavity of appropriate shape in the mold used for overmolding the cut-out metal trace 14.

It can clearly be seen that a power module of the invention is of simple design and enables direct contact to be obtained between the heat dissipating elements of the power module and the cooling means external to the module.

Finally, it should be observed that the invention is not limited to the embodiments described above.

In a variant, the face of the metal trace that is to be put into direct contact with the external cooling means is flush with the corresponding face of the bottom 28 of the package 26.

1. A one-piece power module (12) comprising at least one cut-out metal trace (14), at least one electronic power component (16) electrically connected to the cut-out metal trace, and an electrically insulating material (30; 56) providing the power module with cohesion, the module presenting a cooling face (28) for putting into direct contact with cooling means external to the module, and at least a portion of said cooling face comprising the cut-out metal trace.

2. The power module of claim 1, wherein the cut-out metal trace (14) comprises tracks between which there remain gaps (15), and the cooling face comprises the tracks of the cut-out metal trace (14) and electrically-insulating complementary portions (30; 56) which fill the gaps (15).

3. The power module of claim 1, wherein the complementary portions (30; 56) are overmolded around the tracks of the cut-out metal trace (14).

4. The power module of claim 1, wherein the electrically-insulating material (30) forms a package (26) whose bottom (28) constitutes at least a portion of the cooling face.

5. The power module of claim 4, wherein the package (26) includes an inside space defined by side walls (32) and containing the electronic power component (16) and a means for connection to the cut-out metal trace (14), and a filler material (36) filling the empty space around the electronic power component and a connection means between the side walls (32).

6. A The power module of claim 5. wherein the filler material (36) is selected from a group consisting of a silicone gel, an epoxy and a polyurethane type resin.

7. The power module of claim 1, wherein the electrically-insulating material (56) forms an overmolded block around the cut-out metal trace (14) and the electronic power component (16).

8. The power module of claim 1 wherein tabs (40) support and electrically connect the cut-out metal trace (14) to elements external to the module.

9. The power module of claim 8, wherein the elements external to the power module include means for controlling the power module.

10. The power module of claim 1, wherein the electronic power component (16) is selected from a group consisting of a diode; a MOS type transistor; an IGBT type transistor; and an ASIC type integrated circuit.

11. The power module of claim 1, wherein the electrically-insulating material (30; 56) is selected from a group consisting of a resin of epoxy and polyurethane type.

12. (canceled)

13. (canceled)

14. A power module assembly comprising:
a) at least one power module including at least one cut-out metal trace, at least one electronic power component electrically connected to the cut-out metal trace, and an electrically insulating material providing the power module with cohesion, the power module presenting a cooling face for putting into direct contact with cooling means external to the module, and at least a portion of said cooling face comprising the cut-out metal trace; and
b) a face including the cooling face.

15. The power assembly of claim 14, wherein the assembly includes an assembly package comprising a bottom forming at least a portion of the face including the cooling face of the power module.
